(19) United States
(12) Patent Application Publication
(10) Pub. No.: US 2011/0213580 A1
(43) Pub. Date: Sep. 1, 2011

(54) METHOD FOR FINDING PARAMETERS OF BIOLOGICAL TESTING DEVICE AND METHOD FOR MAKING BIOLOGICAL TESTING SHEETS CORRESPONDING TO THE PARAMETERS

(76) Inventors: Chia-Nan Wang, Kaoshiung City (TW); Chi-Yuan Lin, Kaoshiung City (TW)

(21) Appl. No.: 12/174,623

(22) Filed: Jul. 16, 2008

(51) Int. Cl. G06F 19/00; H05K 13/00

(52) U.S. Cl. 702/123; 29/825

(57) ABSTRACT

A buffer solution is made based on electrode features of a biological testing device. An interference agent for stabilizing measurement signals from the biological testing sheet is prepared. An enzyme is prepared based on parameters of the biological testing device and the electrode properties. An optimum electrode potential is determined and then the properties of the electrodes are reevaluated using potassium ferricyanide and potassium ferrocyanide. Enzyme from an incomplete biological testing sheet is retained, which is dried, covered and cut. The number of sets is determined and the steps repeated to find optimal ingredients and corresponding testing sheets. Sampling and testing of the biological testing sheets using different parameter codes is performed until all parameter codes are tested to determine process completion. Thus, biological testing sheets matching different biological testing devices from different manufactures or biological testing devices are provided.

### FIELD OF THE INVENTION

The present invention relates to a method for finding parameters of a biological testing device and a method for making biological testing sheets corresponding to the parameters so as to increase the convenience of users and lower the cost.

### BACKGROUND OF THE INVENTION

Current commercial biological testing sheets can not be well controlled in the manufacturing processes. The biological testing sheets made at different time will have different qualities. Slightly quality variations generate. In making biological testing sheets, the calculating results must be calibrated by matching different parameters (such as slopes, cutoff distances, enlarged times, etc.) of a biological testing device. Different batches of the same manufactures have such phenomenon. Thus, the biological testing devices of a manufacture are only suited for the biological testing sheets of the same manufacturer. The differences between the processes, steps, and prescriptions, and operators of different manufacturers will generate great differences in the biological testing sheets and biological testing devices. Even preparing the parameters for different manufactures, they are still not matched each other. This induces inconvenience for users, and the cost is increased.

### SUMMARY OF THE INVENTION

Accordingly, the object of the present invention is to provide a method for finding parameters of a biological testing device and a method for making biological testing sheets corresponding to the parameters; in that the biological testing sheet can be inserted to the biological testing device for reaction and calculation so as to make biological testing sheets matching different biological testing devices of different manufactures or make biological testing devices to match biological testing sheets of different manufacturers so as to increase the convenience of users and lower the cost.

To achieve above object, a method for fining parameters of a biological testing device; the method comprises the following steps of: Step 1: selecting one specific parameter code of a biological testing device; Step 2: fining possible effective parameters in manufacturing by using current biological testing sheet with respect to the selected biological testing device parameters in step 1; and recording the parameters; Step 3: determining whether parameters from experiments is within a predetermined range to determine whether it is needed to be adjusted; if necessary, returning to step 2 to finding new parameters; if no, proceeding to the following step; Step 4: finding a relation formula between the parameter codes and the parameters by using prediction tools; Step 5: Finding another specific parameter code in the biological testing device, and repeating steps 2 to 5 until all the parameter codes in the biological testing device have been tested or the specific parameter code is tested; and Step 6: collecting and ordering the data gathered in step 1 to step 5 and depicting the parameter code table of the biological testing device; sampling and test some of the parameter codes by using other biological testing sheet for determining whether the parameters are near the parameter codes; if not, repeat the step 1; if yes, the work of searching parameters of biological testing sheet is complete.

Furthermore, the present invention provide a method for making a biological testing sheet according to the present invention comprising the following steps of: Step 1: making a buffer solution by electrode features of the biological testing device so that the pH value (Acid Test) of the solution is not changed apparently due to external strong acid or strong alkaline; Step 2: preparing interference agent, for stabilizing measure signals of the biological testing sheet; preparing electronic mediator based on the parameters of biological testing device and the electrode property for speeding the transfer of electrons there between and reducing over-voltage so that the interference agent will generate oxidation-reduction reaction in a lower potential and is detected by electrodes to increase the selectivity of the electrode surface; Step 3: preparing Enzyme according to the parameters of biological testing device and the electrode property. Step 4: Preparing ratio of the Working electrode of the biological testing sheet and the Reference electrode; and finding an optimum potential by using Cyclic Voltammetry method or Amperometry method, etc. Step 5: checking re-appearance property of the electrode by using Potassium ferricyanide (K₃Fe(CN)₆, and Potassium ferrocyanide K₄Fe(CN)₆ and adjusting the repeatition, re-appearance and linearity of the electron transfer by the oxidation-reduction variations between the Potassium ferricyanide (K₃Fe(CN)₆, and Potassium ferrocyanide K₄Fe(CN)₆; Step 6: retaining the enzyme from the step 3 to the electrode reaction working area of an incomplete biological testing sheet; and drying, covering, and cutting the biological testing sheet so as to complete the work of manufacturing the biological testing sheet; Step 7: setting number of sets by statistical experiment design or Taguchi methods, repeating steps 1 to 6 to make biological testing sheet and testing samples of the biological testing sheets to fine an optimum ingredients; and Step 8: repeating the work of making biological testing sheet by the optimum ingredients got from step 7, sampling and testing the biological testing sheets by using different parameter codes of the biological testing sheets until all the parameter codes of the biological testing sheet are tested; if the result is not matched, the process is returned to step 1 for making the biological testing sheet again; if they are matched, the work of making biological testing sheet is completed.

Above method of making biological testing sheet uses the parameters corresponding to the parameter codes of the biological testing sheet so that the biological testing sheet can be inserted to the biological testing device for reaction and calculation to make biological testing sheets matching different biological testing devices of different manufactures or make biological testing devices to match biological testing sheets of different manufacturers to increase the convenience of users and lower the cost.

The various objects and advantages of the present invention will be more readily understood from the following detailed description when read in conjunction with the appended drawing.

### BRIEF DESCRIPTION OF THE DRAWINGS

FIG. 1 shows the flow diagram about the steps of finding parameters of biological testing devices according to the present invention.

FIG. 2 is a flow diagram for making biological testing sheets according to the present invention.

### DETAILED DESCRIPTION OF THE INVENTION

In order that those skilled in the art can further understand the present invention, a description will be provided in the following in details. However, these descriptions and the appended drawings are only used to cause those skilled in the art to understand the objects, features, and characteristics of the present invention, but not to be used to confine the scope and spirit of the present invention defined in the appended claims.

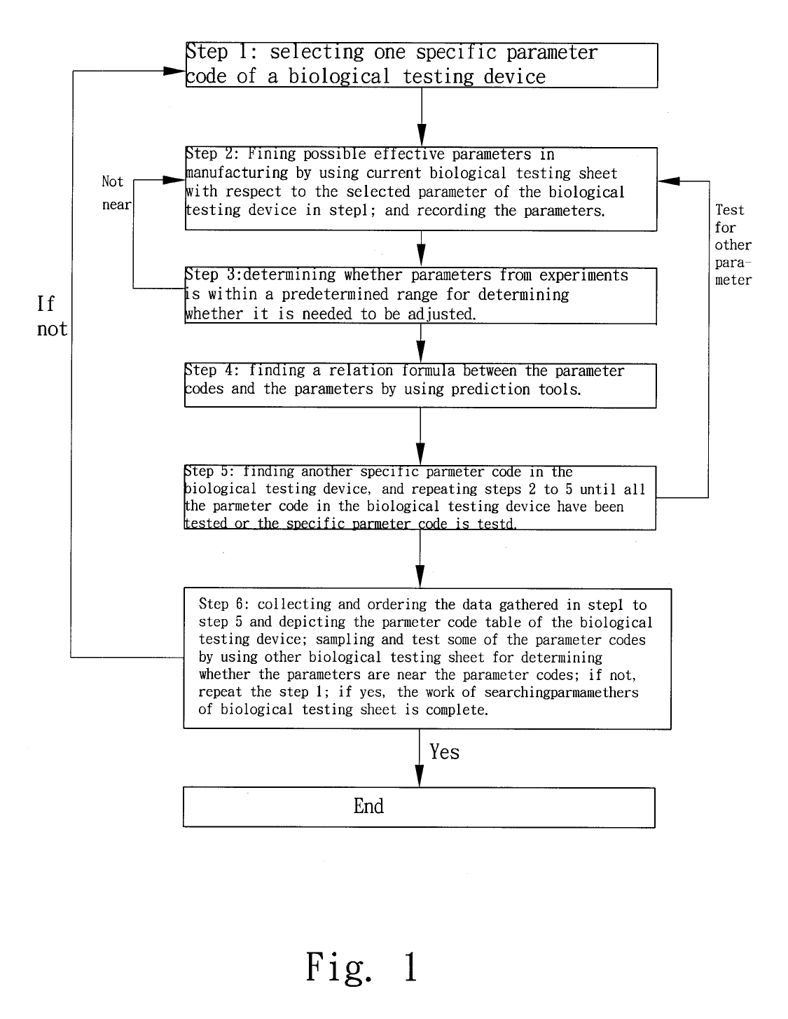

With referring to FIG. 1, the method for fining parameters of biological testing device according to the present invention is illustrated. The method comprises the following steps of:

Step 1: selecting one specific parameter code of a biological testing device;

Step 2: Fining possible effective parameters in manufacturing (such as slopes, cutoff distances, amplifying times, etc.) by using current biological testing sheet (such as a sheet for one specific manufacturer or other biological testing sheets) with respect to the selected parameter of the biological testing device in step 1; and recording the parameters;

Step 3: determining whether parameters from experiments is within a predetermined range for determining whether it is needed to be adjusted; if necessary, returning to step 2 to finding new parameters; if no, proceeding to the following step;

Step 4: finding a relation formula between the parameter codes and the parameters by using prediction tools (such as regression, gray theory, neural network, etc.)

Step 5: Finding another specific parameter code in the biological testing device, and repeating steps 2 to 5 until all the parameter codes in the biological testing device have been tested or the specific parameter code is tested.

Step 6: collecting and ordering the data gathered in step 1 to step 5 and depicting the parameter code table of the biological testing device; sampling and test some of the parameter codes by using other biological testing sheet (such as biological testing sheet made of another manufacturer) for determining whether the parameters are near the parameter codes; if not, repeat the step 1; if yes, the work of searching parameters of biological testing sheet is complete.

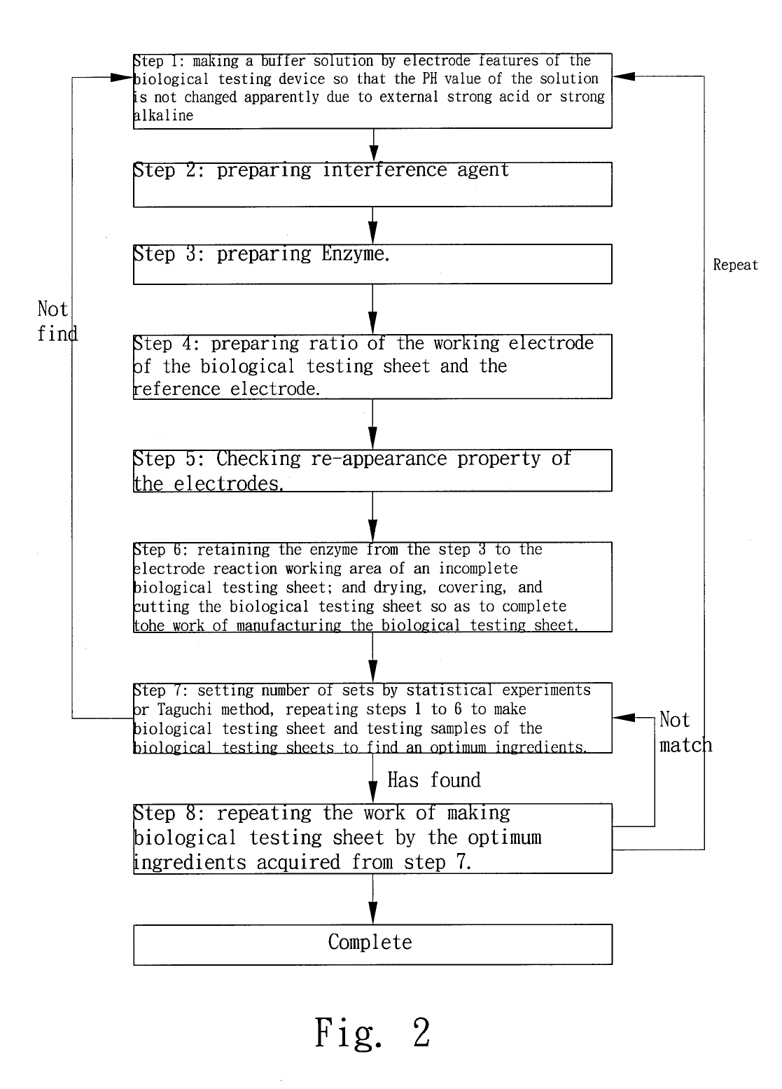

By above mentioned method, after the parameters of the biological testing sheet are found, the parameters are used to make biological testing sheet corresponding to the biological testing sheet, as shown in FIG. 2. Moreover, the method for making a biological testing sheet according to the present invention comprises the following steps of:

Step 1: making a buffer solution by electrode features of the biological testing device so that the pH value (acid test) of the solution is not changed apparently due to external strong acid or strong alkaline, for example the buffer solution is made by mixing phthalic acid- potassium acid phthalate (H₂C₈H₄O₄—KHC₆H₄(COO)₂) and Boric acid-sodium borate H₃BO₃—Na₂B₄O₇ with a pH value between 3.6˜8.05.

Step 2: preparing interference agent, such as PVP, PVA, Cellulose, etc., with a volume percentage of 0.5%˜8.0% for stabilizing measure signals of the biological testing sheet; preparing electronic mediator based on the parameters of biological testing device and the electrode property for speeding the transfer of electrons there between and reducing over-voltage so that the interference agent will generate oxidation-reduction reaction in a lower potential and is detected by electrodes to increase the selectivity of the electrode surface. The contents of the electron mediator are between 3%˜40%.

Step 3: preparing Enzyme (such as Glucose Oxidase, Alcohol Dehydrogenase, etc.) according to the parameters of biological testing device and the electrode property. The contents of the enzyme is between 0.5%˜25%.

Step 4: Preparing ratio of the working electrode of the biological testing sheet and the reference electrode; and finding an optimum potential by using Cyclic Voltammetry method or Amperometry method, etc.

Step 5: checking re-appearance property of the electrodes by using Potassium ferricyanide (K3Fe(CN)6, and Potassium ferrocyanide K4Fe(CN)6 and adjusting the repetition, re-appearance and linearity of the electron transfer by the oxidation-reduction variations between the Potassium ferricyanide (K3Fe(CN)6, and Potassium ferrocyanide K4Fe(CN)6.

Step 6: retaining the enzyme from the step 3 to the electrode reaction working area of an incomplete biological testing sheet; and drying, covering, and cutting the biological testing sheet so as to complete the work of manufacturing the biological testing sheet.

Step 7: setting number of sets by statistical experiments or Taguchi methods, repeating steps 1 to 6 to make biological testing sheet and testing samples of the biological testing sheets to find an optimum ingredients;

Step 8: repeating the work of making biological testing sheet by the optimum ingredients acquired from step 7, sampling and testing the biological testing sheets by using different parameter codes of the biological testing sheets until all the parameter codes of the biological testing sheet are tested; if the result is not matched, the process is returned to step 1 for making the biological testing sheet again; if they are matched, the work of making biological testing sheet is completed.

Above method of making biological testing sheet uses the parameters corresponding to the parameter codes of the biological testing sheet so that the biological testing sheet can be inserted to the biological testing device for reaction and calculation to make biological testing sheets matching different biological testing devices of different manufactures or make biological testing devices to match biological testing sheets of different manufacturers so as to increase the convenience of users and lower the cost.

The present invention is thus described; it will be obvious that the same may be varied in many ways. Such variations are not to be regarded as a departure from the spirit and scope of the present invention, and all such modifications as would be obvious to one skilled in the art are intended to be included within the scope of the following claims.

What is claimed is:

1. A method for fining parameters of a biological testing device; the method comprising the following steps of:
Step 1: selecting one specific parameter code of a biological testing device;
Step 2: fining possible effective parameters in manufacturing by using current biological testing sheet with respect to the selected biological testing device parameters in step 1; and recording the parameters;
Step 3: determining whether parameters from experiments is within a predetermined range to determine whether it is needed to be adjusted; if necessary, returning to step 2 to finding new parameters; if no, proceeding to the following step;
Step 4: finding a relation formula between the parameter codes and the parameters by using prediction tools;
Step 5: Finding another specific parameter code in the biological testing device, and repeating steps 2 to 5 until all the parameter codes in the biological testing device have been tested or the specific parameter code is tested; and
Step 6: collecting and ordering the data gathered in step 1 to step 5 and depicting the parameter code table of the biological testing device;
sampling and testing some of the parameter codes by using other biological testing sheet for determining whether the parameters are near the parameter codes; if not, repeat the step 1; if yes, the work of searching parameters of biological testing sheet is complete.

2. A method for making a biological testing sheet according to claim 1, comprises the following steps of:
Step 1: making a buffer solution by electrode features of the biological testing device so that the pH value (acidity and alkalinity) of the solution is not changed apparently due to external strong acid or strong alkaline;
Step 2: preparing interference agent for stabilizing measure signals of the biological testing sheet; preparing electronic mediator based on the parameters of biological testing device and the electrode property for speeding the transfer of electrons there between and reducing over-voltage so that the interference agent will generate oxidation-reduction reaction in a lower potential and is detected by electrodes to increase the selectivity of the electrode surface;
Step 3: preparing Enzyme according to the parameters of biological testing device and the electrode property;
Step 4: Preparing ratio of the working electrodes of the biological testing sheet and the reference electrode; and finding an optimum potential by using Cyclic Voltammetry method or Amperometry method or other method;
Step 5: checking re-appearance property of the electrodes by using Potassium ferricyanide (K₃Fe(CN)₆, and Potassium ferrocyanide K₄Fe(CN)₆ and adjusting the repetition, re-appearance and linearity of the electron transfer by the oxidation-reduction variations between the Potassium ferricyanide (K₃Fe(CN)₆, and Potassium ferrocyanide K₄Fe(CN)₆;
Step 6: retaining the enzyme from the step 3 to the electrode reaction working area of an incomplete biological testing sheet; and drying, covering, and cutting the biological testing sheet so as to complete the work of manufacturing the biological testing sheet;
Step 7: setting number of sets by statistical experiment design or Taguchi methods, repeating steps 1 to 6 to make biological testing sheet and testing samples of the biological testing sheets to fine an optimum ingredients; and
Step 8: repeating the work of making biological testing sheet by the optimum ingredients got from step 7, sampling and testing the biological testing sheets by using different parameter codes of the biological testing sheets until all the parameter codes of the biological testing sheet are tested; if the result is not matched, the process is returned to step 1 for making the biological testing sheet again; if they are matched, the work of making biological testing sheet is completed.

3. The method for making a biological testing sheet as claimed in claim 2, wherein the volume of the interference is between 0.5%˜8.0%.

4. The method for making a biological testing sheet as claimed in claim 2, wherein the contents of the electron mediator is between 3%˜40%.

5. The method for making a biological testing sheet as claimed in claim 2, wherein the contents of the enzyme is between 0.5%˜25%.
